(19) United States
(12) Patent Application Publication
(10) Pub. No.: US 2024/0302453 A1
(43) Pub. Date: Sep. 12, 2024

(54) METHOD, OPTICAL SYSTEM, TEST DEVICE AND ARRANGEMENT

(71) Applicant: Carl Zeiss SMT GmbH, Oberkochen (DE)

(72) Inventors: Stefan Krone, Ellwangen (DE); Sven Urban, Neu-Ulm (DE)

(21) Appl. No.: 18/666,211

(22) Filed: May 16, 2024

Related U.S. Application Data
(63) Continuation of application No. PCT/EP2022/083576, filed on Nov. 29, 2022.

(30) Foreign Application Priority Data
Dec. 1, 2021 (DE) 10 2021 213 610.9

(51) Int. Cl. G01R 31/58; G01R 27/16; G03F 7/00

(52) U.S. Cl. CPC G01R 31/58; G01R 27/16; G03F 7/70808; G03F 7/70891

(57) ABSTRACT

A method for checking an interface for the wired transmission of electrical signals to an electronics unit, arranged in a vacuum-tight housing, of an optics module comprises: a) coupling a first bundle of the interface to the electronics unit; b) connecting a test device to a free end of the first bundle; c) applying an electrical test signal generated by the test device to a specific pair of electrical lines of the first bundle; d) acquiring an electrical response signal from the specific pair of electrical lines; e) comparing the acquired response signal with a response signal predetermined for the specific pair, and f) determining whether a defect is present in one of the electrical lines of the pair on the basis of the comparison.

### CROSS-REFERENCE TO RELATED APPLICATIONS

The present application is a continuation of, and claims benefit under 35 USC 120 to, international application No. PCT/EP2022/083576, filed Nov. 29, 2022, which claims benefit under 35 USC 119 of German Application No. 10 2021 213 610.9, filed Dec. 1, 2021. The entire disclosure of each of these applications is incorporated by reference herein.

### FIELD

The present disclosure relates to a method for checking an interface, to a method for producing an optical system, to an optical system, to a test device and to an arrangement.

### BACKGROUND

Microlithography is used for producing microstructured component parts, such as for example integrated circuits. The microlithography process is performed using a lithography apparatus, which has an illumination system and a projection system. The image of a mask (reticle) illuminated by way of the illumination system is in this case projected by way of the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light having a wavelength in the range from 0.1 nm to 30 nm, such as 13.5 nm, are currently under development. Since most materials absorb light of this wavelength, EUV lithography apparatuses typically use reflective optics, that is to say mirrors, instead of-as previously-refractive optics, that is to say lenses.

Furthermore, beam guidance in EUV lithography apparatuses usually takes place in a vacuum, since the EUV radiation would be greatly attenuated when propagating in a gas atmosphere. The EUV lithography apparatus therefore has one or more vacuum housings. EUV lithography apparatuses are therefore of considerably more complex structure than lithography apparatuses whose working light has a higher wavelength.

Some electronics, such as for example actuation electronics for actuable optical elements, are arranged in a vacuum housing of the lithography apparatus due to the system design. The electronics themselves are in this case typically accommodated in a vacuum-tight housing, since the electronics are not designed for operation under vacuum, but rather use atmospheric pressure, for example. Cable connections are usually used to transmit signals from a control computer outside the vacuum housing to the electronics. The cable connection is in this case guided via multiple sections and plug connectors, such as for example via a vacuum interface on the vacuum housing and a further interface on the vacuum-tight housing of the electronics. Multiple cable bundles often are connected via respective plug connectors in this case. It may be the case here that individual contacts are not produced correctly, that one of the plug connectors breaks when connected or that two plug connectors are mixed up. All this may lead to the electronics possibly not operating as intended. This may be followed by burdensome troubleshooting.

During operation of electronics arranged in the vacuum housing, it is to be borne in mind here that it is not possible to dissipate heat through convection. The electronics therefore have to be cooled in another way, for example by way of a water cooling system. However, integrating the water cooling system when constructing the lithography apparatus can be highly burdensome. The lithography apparatus is typically already in a high state of integration when the water cooling system is able to be put into operation. Since the water cooling system is operational for the operation of the electronics, a first system test, in which for example correct cabling and wiring of the electronics is checked, is usually able to take place only at this later time when the lithography apparatus is constructed. If a defect is identified in this system test, then the lithography apparatus usually has to be dismantled again from the high state of integration in order to rectify the defect, which is highly burdensome.

### SUMMARY

The present disclosure seeks to provide an improved method for checking an interface.

According to a first aspect, what is proposed is a method for checking an interface for the wired transmission of electrical signals to an electronics unit, arranged in a vacuum-tight housing, of an optics module. The optics module has a number of displaceable optical elements for guiding radiation, wherein at least one actuator/sensor device for displacing the optical element and/or for acquiring a position of the optical element is assigned to the respective optical element. The electronics unit is configured to actuate the respective actuator/sensor device on the basis of electrical signals received via the interface. The interface comprises at least one first bundle containing a multiplicity of electrical lines, which first bundle is able to be coupled to corresponding contacts of the electronics unit. The method comprises the steps of:
a) coupling the first bundle to the electronics unit,
b) connecting a test device to a free end of the first bundle,
c) applying an electrical test signal generated by the test device to a specific pair of electrical lines of the first bundle,
d) acquiring an electrical response signal from the specific pair of electrical lines,
e) comparing the acquired response signal with a response signal predetermined for the specific pair, and
f) determining whether a defect is present in one of the electrical lines of the pair on the basis of the comparison.

This method can allow that the signal connection, which is provided by way of the interface to the electronics unit, is able to be checked easily and reliably. This check may take place independently of any operation of the optics module. In other words, a cooling system, such as a fluid cooling system, used for the operation of the optics module does not yet have to be ready for operation. In other words, the interface is able to be checked independently of the readiness for use of any other systems used for the operation of the optics module.

The vacuum-tight housing is configured to receive the electronics unit and to keep it under atmospheric pressure, even when the optics module is installed in a vacuum housing. Atmospheric pressure is understood here to mean for example a pressure range of 10 hectoPascals (hPa)-10,000 hPa. The vacuum-tight housing may be filled, during operation of the optics module, with a specific gas, such as for example nitrogen, carbon dioxide or argon, or else with a mixture of multiple gases, such as air. The vacuum-tight housing may consist of metal.

The optical elements can be arranged outside the vacuum-tight housing. The optical elements may be for example mirrors, such as micromirrors, that is to say mirrors having a side length of less than 1 mm, or lenses or optical gratings and/or filters. A respective optical component part is able to be displaced by way of the assigned actuator/sensor device and/or a position of the optical element may be acquired by way of the actuator/sensor device. The position information may be processed in order to control and/or regulate the respective optical element and/or the optics module.

The optics module is designed for example as a multi-mirror arrangement, such as a micromirror array (MMA). Such an arrangement may comprise more than 100, such as more than 1000, as an example more than 10,000, for example more than 100,000 individually actuable mirrors. These may be mirrors for reflecting EUV radiation.

The fact that the optical elements are configured to guide radiation is understood to mean in particular that the respective optical element is configured to manipulate the radiation, in particular by deflecting or diverting the radiation through reflection or refraction. The respective optical component part may also modify or influence other properties of the radiation, such as a polarization, a phase and/or a wavelength.

The electronics unit is configured to actuate the actuator/sensor devices of the optics module. The electronics unit can be implemented in the form of hardware for this purpose. If the implementation is in the form of hardware, the electronics unit may be designed as a device or as part of a device, for example as a computer or as a microprocessor or as a control computer or as an embedded system.

The electronics unit can comprise signal processing logic and power electronics that provide the operating voltage used for the operation of the actuator/sensor devices, such as in the form of a modulated actuation voltage. The signal processing logic is configured to receive the electrical signals from outside the optics module, for example from a central control computer or the like, and to process the received signals. The signal processing logic therefore forms a control and regulation circuit for the actuator/sensor devices.

The term electrical signals is understood here to mean digital or else analogue electrical signals, wherein an operating voltage by way of which electrical energy is provided for the operation of the optics module and/or of the electronics unit also constitutes an electrical signal. Provision may be made for multiple lines for providing a respective operating voltage, wherein the respective operating voltage is for example a voltage of 3.3 V, 5 V, 12 V, up to 30 V, up to 60 V or even up to 120 V. The electrical signal may comprise a data signal, which may comprise a control signal for actuating the optics module, such as the actuator/sensor devices, or else a measured data signal from the actuator/sensor devices.

The term “interface” is understood here in particular to mean the entire signal transmission path from a respective external unit to the electronics unit. The interface thus comprises a number of cable bundles, plug connectors and the like. The interface may have a constant multiplicity of electrical lines running in parallel along its course. In some embodiments, the interface may however also comprise, in sections, a different multiplicity of electrical lines running in parallel; by way of example, an individual operating voltage line in a plug connector may be placed onto a multiplicity of contact pins of the plug connector.

The interface comprises, in sections, for example up to 100 parallel electrical lines, or up to 400 parallel electrical lines, or even up to 1000 parallel electrical lines.

The interface comprises at least one first bundle containing a multiplicity of electrical lines, which first bundle is able to be coupled to corresponding contacts of the electronics unit. The first bundle thus forms a first section of the interface, wherein the interface may be extended by further sections, for example by respective further bundles. The multiplicity of electrical lines may be arranged in one or in multiple cables. In other words, the respective bundle may comprise more than one cable with in each case one or more electrical lines. The bundle may additionally have, on one side, multiple separate plug connectors for connection to the electronics unit or to a further bundle. The contacts of the electronics unit are arranged for example in one or more plug connectors on the electronics unit. The one or more plug connectors may in this case be designed as sockets or as plugs. The first bundle has the respectively matching socket(s) and/or plug(s) on one end.

In a first step a), the first bundle is coupled to the electronics unit. By way of example, a plug of the first bundle is plugged into the socket of the electronics unit. In order to check whether the plug connection has established intended electrical contact, this is checked by way of a test device. In a second step b), the test device is therefore connected to a free end of the first bundle. In a third step c), an electrical test signal generated by the test device is applied to a specific pair of electrical lines of the first bundle. In a fourth step d), an electrical response signal from the specific pair of electrical lines is acquired. In a fifth step e), the acquired response signal is compared with a response signal predetermined for the specific pair. On the basis of this comparison, in a sixth step f), it is determined whether there is a defect in one of the electrical lines of the pair.

A defect may be for example a lack of electrical contact between the electrical lines or a short circuit between the electrical lines. An electrical resistance that is excessively high or excessively low in relation to a setpoint value may also be an indicator of a defect. An incorrect impedance value and/or an impedance value that deviates from a setpoint value may additionally be an indicator of a defect.

The test device can be adapted specifically for use in this method. Such a test device is described in detail below.

In some embodiments, the optics module may have multiple identical electronics units and the interface of the respective electronics unit may comprise multiple plugs or sockets on the respective electronics unit. The bundle then comprises, on the electronics unit side, multiple matching corresponding sockets or plugs. It may then be the case that a socket or plug of a bundle that is assigned to a first electronics unit is incorrectly coupled to the corresponding plug or socket on a second electronics unit. Part of the first bundle of the first electronics unit would then thus be coupled incorrectly to the second electronics unit. Such mixing up of the sockets or plugs of a respective bundle may be determined for example on the basis of a ground potential that is constant for a respective electronics unit. By way of example, each separately formed socket or each separately formed plug on the respective electronics unit has at least one ground pin. A ground pin is a contact pin that is coupled to ground potential. Ground pins present in different sockets or plugs can be short-circuited in the electronics unit since they have the same ground potential. In other words, an electrical resistance between the ground pins of different plugs or sockets of a respective electronics unit is zero. However, this does not apply to ground pins between different electronics units, which may be used to conclude that something has been mixed up when coupling the bundle.

According to one embodiment of the method, steps c)-f) are performed for each pair of electrical lines of the first bundle.

In other words, any combinatorial possibility in which the electrical lines of the first bundle are able to be arranged in pairs is tested.

According to an embodiment of the method, the interface is expanded by a further bundle of electrical lines by coupling the further bundle to the first bundle. An extended bundle is thus provided. Steps b)-f) are then performed in relation to the extended bundle.

It could also be said that the interface is supplemented with a further section and is then checked again.

The further bundle is coupled to the first bundle by way of a suitable plug connector. A housing feedthrough, such as for example through a wall of the vacuum-tight housing or else of a vacuum housing, may be involved here.

The interface may thereby be extended section by section, wherein the interface can be checked following each extension. It is thus possible to respond immediately to possible defects. Burdensome troubleshooting is thus also dispensed with, since an identified defect is present in the respectively last-added section due to the stepwise process. Without this process, on the other hand, troubleshooting is used when the defect is identified only in a test mode, in which the interface is able to be checked only when it already comprises multiple sections.

According to an embodiment of the method, the electrical test signal comprises a DC voltage signal or an AC signal for determining an electrical resistance, an AC voltage signal or an AC signal with a specific frequency for determining a specific impedance and/or an AC voltage signal or an AC signal with a changeable frequency for determining an impedance characteristic.

When the electrical test signal is for example a DC voltage signal generated by a voltage source and the intention is to determine a resistance, the corresponding electrical response signal is the current flow that arises due to the DC voltage signal. By contrast, the electrical test signal may be a DC signal generated by a current source and having a specific current flow, wherein the corresponding electrical response signal is then the voltage that is used to achieve the current flow.

In some embodiments, the test signal comprises a digitally modulated voltage signal, such as a data signal, and the response signal is a corresponding digitally modulated voltage signal generated by the electronics unit. This may also be referred to for example as a challenge-response method.

Spectral analysis may be able to be performed on the basis of the electrical test signal.

The electrical test signal may have different signal shapes, such as when it is an AC voltage signal. Examples of these are a sinusoidal signal profile, a square-wave signal profile, a sawtooth signal profile or even a triangular-wave signal profile. The AC voltage signal may be shifted with respect to a zero potential.

The DC voltage signal may be temporally modulated. For example, the DC voltage signal may consist of an overlap between a constant voltage value and an AC voltage signal.

According to an embodiment of the method, prior to step a), the predetermined response signal for each pair of contacts of the electronics unit is determined by applying the test signal to a respective pair of contacts of the electronics unit and acquiring the response signal.

This step may also be referred to as calibration. This step may be performed individually for each module even in the case of structurally identical electronics units or optics modules, such that tolerances between different modules do not lead to an incorrect evaluation. This thus can allow for particularly precise checking of the respective interface.

According to an embodiment of the method, the optics module is part of an optical system superordinate to the optics module, wherein the optics module is arranged in a vacuum housing of the optical system during operation of the optical system and the interface comprises a bundle running through the vacuum housing of the optical system and a vacuum interface arranged on the vacuum-tight housing and/or on the vacuum housing.

It is pointed out that the vacuum interface is part of the interface only when the optics module is integrated into the vacuum housing and a corresponding bundle has been connected to the vacuum interface.

According to an embodiment of the method, the electronics unit is actively cooled during operation of the optics module by way of a fluid cooling system.

Since the electronics unit has high thermal power loss during operation, the optics module has to be cooled during operation. Fluid cooling systems, such as a water cooling system, are particularly suitable for this. This is particularly true when the optics module is arranged in a vacuum housing of the optical system. Such cooling systems are highly burdensome in terms of integration and involve for example a long start-up time. It is therefore particularly desirable in these cases for at least the interface to already be able to be checked without the complex cooling system being provided and ready for operation, this being possible by virtue of the proposed method.

According to an embodiment of the method, the electronics unit has a first electronics region containing a number of electrical and/or electronic component parts and that generates, during operation, a first thermal power loss that is less than or equal to a predetermined threshold value, and has a second electronics region containing a number of electrical and/or electronic component parts and that generates, during operation, a second thermal power loss above the predetermined threshold value, wherein the first electronics region is able to be operated independently of the second electronics region, and wherein the method furthermore comprises:
operating the first electronics region, and
checking an intended function of the first electronics region.

The first electronics region may be operated by way of the test signal. In this case, more than just two electrical lines of the bundle may be loaded. Provision may furthermore be made for analogue and/or digital data signals to be transmitted via a respective electrical line of the bundle.

In this embodiment, only the first electronics region is operated. In other words, the second electronics region is not operated, that is to say for example remains voltage-free and deactivated.

The threshold value for the thermal power loss is selected such that the first thermal power loss is dissipated, without active cooling of the electronics unit or of the optics module, solely via heat transfer in solid bodies and/or thermal radiation. In other words, no active cooling is used for the operation of the first electronics region. The first electronics region may therefore already be operated for test purposes when an active cooling system, such as a fluid cooling system, is not yet provided and/or operational. The test mode likewise makes it possible to check the interface. It may furthermore also be checked in the test mode whether a transmission quality of data signals is good enough for active operation of the optics module, that is to say for example has a sufficient signal strength.

According to a second aspect, what is proposed is a method for producing an optical system. The optical system comprises at least one optics module arranged in a vacuum housing and having a number of displaceable optical elements for guiding radiation in the optical system, wherein at least one actuator/sensor device for displacing the optical element and/or for acquiring a position of the optical element is assigned to the respective optical element, and wherein the optics module has an electronics unit, arranged in a vacuum-tight housing, for actuating the respective actuator/sensor device on the basis of electrical signals received via an interface. The interface comprises a multiplicity of sections, wherein the respective section comprises a bundle containing a multiplicity of electrical lines, wherein, during the production of the optical system, the interface is supplemented with the respective section by coupling the respective bundles, and wherein the interface is checked using the method according to the first aspect following each coupling of the respective further bundle.

This method can allow that, following each production step of the optical system, the intended function of the interface is checked, and this thus avoids the optical system having to be dismantled again when such a check, only after production is complete, reveals that the interface has a defect.

The embodiments and features described for the method according to the first aspect apply correspondingly to the proposed method for producing the optical system. The optics module and the interface may have the features that have been explained with regard to the optics module and the interface in relation to the method of the first aspect. The optical system produced as proposed forms an optical system as described below with reference to the third aspect and may have the features thereof.

The optical system is produced as follows, merely by way of example:
providing the electronics unit,
coupling a first bundle comprising multiple electrical lines to the electronics unit in order to provide a first section of the interface,
checking the first section of the interface using the method according to the first aspect,
integrating the electronics unit into the optics module, wherein the first bundle is coupled to a second bundle of electrical lines that is arranged on the optics module in order to provide a second section of the interface,
checking the interface comprising the first and the second section using the method according to the first aspect,
arranging the optics module in the vacuum housing of the optical system, wherein the second bundle is coupled to a third bundle of electrical lines that is arranged on the vacuum housing in order to provide a third section of the interface, and
checking the interface comprising the first, second and third section using the method according to the first aspect.

According to a third aspect, what is proposed is an optical system having a number of optics modules. The respective optics module has:
a number of displaceable optical elements for guiding radiation in the optical system,
a number of actuator/sensor devices, wherein the respective actuator/sensor device is configured to displace the assigned optical element and/or to acquire a position of the assigned optical element, wherein at least one of the actuator/sensor devices is assigned to the respective optical element,
a vacuum-tight housing,
an electronics unit arranged in the vacuum-tight housing and configured to actuate the respective actuator/sensor device on the basis of electrical signals received via a wired interface, wherein an input, coupled to the interface, of the electronics unit comprises a multiplicity of electrical lines that has a specific wiring configuration with electrical and/or electronic components, such that a respective pair of electrical lines has a predetermined passive input behaviour that is able to be determined using an electrical test signal transmitted via the interface.

The optical system can be a projection optical unit of the projection exposure apparatus. However, the optical system may also be an illumination system. The projection exposure apparatus may be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light of between 30 nm and 250 nm.

The optical system may furthermore be part of a superordinate optical system, such as a beamforming and illumination system of a lithography apparatus; for example, the optical system is designed as a multi-mirror module that is arranged in the beamforming and illumination system. In this case, the optical system is arranged in an evacuable chamber or a vacuum housing.

Since a respective pair of lines of the input of the electronics unit has a specific wiring configuration with a predetermined passive input behaviour, the function of the interface is able to be checked following each integration step, such as an expansion or extension of the interface, using the method according to the first aspect.

The term “passive input behaviour” is understood here in particular to mean that the behaviour of the interface is tested without active operation of the electronics unit. By way of example, a resistance or an impedance is determined without active component parts, such as logic gates or the like, being supplied with their operating voltage. The test signal used to determine the passive input behaviour is designed in particular as described with reference to the method according to the first aspect.

The embodiments and features described for the method according to the first aspect apply correspondingly to the proposed optical system. The optics module and the interface may have the features that have been explained with regard to the optics module and the interface in relation to the method of the first aspect. The optical system can be produced using the method according to the second aspect.

According to one embodiment of the optical system, the electrical and/or electronic components comprise a resistor, a capacitor, an inductor and/or a diode.

Provision may be made for the electronics unit to have dedicated electrical or electronic components as a passive wiring configuration of the input. Dedicated components are not components that are integrated in functional modules, such as an application-specific integrated circuit (ASIC), a processor, a memory module or the like, but rather are present specifically to check the interface. These components do not influence active operation of the electronics unit. In other words, the electronics unit is able to operate even without these components.

According to an embodiment of the optical system, the optical system is designed as a lithography apparatus with a vacuum housing, wherein the respective optics module is arranged in the vacuum housing, and wherein the lithography apparatus comprises a fluid cooling system for cooling the respective optics module during operation of the lithography apparatus.

The possibility of checking the interface following a respective production step can be desirable in the case of such optical systems, since otherwise the fluid cooling system may have to be provided as a whole and put into operation for the check, which constitutes a very large amount of effort.

According to an embodiment of the optical system, the respective electronics unit has a first electronics region containing a number of electrical and/or electronic component parts and that generates, during operation, a thermal power loss that is less than or equal to a predetermined threshold value, and has a second electronics region containing a number of electrical and/or electronic component parts and that generates, during operation, a thermal power loss above the predetermined threshold value, and wherein the first electronics region is able to be operated independently of the second electronics region.

The threshold value for the thermal power loss is selected such that the first thermal power loss is dissipated, without active cooling of the electronics unit or of the optics module, solely via heat transfer in solid bodies and/or thermal radiation. In other words, no active cooling is used for the operation of the first electronics region. The first electronics region may therefore already be operated for test purposes when an active cooling system, such as a fluid cooling system, is not yet provided and/or operational. The test mode likewise makes it possible to check the interface. It may furthermore also be checked in the test mode whether a transmission quality of data signals is good enough for active operation of the optics module, that is to say for example has a sufficient signal strength.

In this embodiment, an expanded check of the interface that goes beyond checking the passive input behaviour is able to take place. The first electronics region may be actuated by way of the test signal. In this case, for example more than just two electrical lines of the bundle may be loaded. Provision may furthermore be made for analogue and/or digital data signals to be transmitted via a respective electrical line of the bundle.

According to a fourth aspect, what is proposed is a test device for checking an interface for the wired transmission of electrical signals to an electronics unit, arranged in a vacuum-tight housing, of an optics module. The interface comprises at least one first bundle containing a multiplicity of electrical lines, which first bundle is coupled to corresponding contacts of the electronics unit. The test device has:
a plug connector for connecting the test device to a free end of the first bundle of electrical lines,
a generation unit, which is configured to generate an electrical test signal for checking a pair of electrical lines,
an acquisition unit, which is configured to acquire a response signal when the test signal is applied to the pair of electrical lines,
a multiplexing unit for connecting a respective pair of electrical lines of the bundle coupled to the plug connector to the generation unit and to the acquisition unit,
a comparison unit for comparing the acquired response signal for the pair of electrical lines with a response signal predetermined for the pair, and
a determination unit for determining whether a defect is present in one of the electrical lines of the pair on the basis of the comparison.

This test device may be used to check the interface in the method according to the first aspect and/or the second aspect, for example to check the interface of the optical system according to the third aspect, while the optical system is being produced.

The test device is implemented at least partially in hardware form. The plug connector and the multiplexing unit are designed in the form of hardware. The generation unit, acquisition unit, comparison unit and determination unit may each be implemented in the form of hardware and/or software. In the case of an implementation in the form of hardware, the respective unit may be designed for example as a computer or as a microprocessor. In the case of an implementation in the form of software, the respective unit may be designed as a computer program product, as a function, as a routine, as an algorithm, as part of a program code or as an executable object.

The generation unit is configured to generate the test signal. By way of example, the generation unit comprises a function generator. The test signal may have the features as have already been described with reference to the method according to the first aspect.

The acquisition unit comprises for example a current and voltage measuring unit that is configured to measure a current signal and a voltage signal of a respective amplitude and/or at a respective frequency.

The multiplexing unit is configured to couple in each case two electrical lines of the bundle that is connected to the plug connector to the generation unit and to the acquisition unit.

In one embodiment, the multiplexing unit has for example an input having a number greater than two of electrical lines, and has an output having two electrical lines. The output is coupled to the generation unit and to the acquisition unit, and the input is coupled to the plug connector, wherein the respective electrical line of the output is coupled to a respective contact pin of the plug connector. The multiplexing unit comprises a number of switching states, wherein, in the respective switching state, exactly two electrical lines of the input are switched onto, that is to say electrically connected to, the two electrical lines of the output.

In an embodiment, provision may be made for multiple pairs of generation unit and acquisition unit each able to be coupled to a respective pair of electrical lines by way of the multiplexing unit, such that the respective test signal is able to be applied to multiple pairs of electrical lines simultaneously or in parallel and the respective response signal is able to be acquired. This can be desirable in the case of a large number of electrical conductors in the respective bundle of the interface in order to shorten the duration for checking the interface.

The comparison unit may for example comprise a storage unit in which the response signal predetermined for the respective pair of electrical lines is stored and from which the respective response signal for the comparison is able to be retrieved. The comparison unit may furthermore comprise an analysis unit that is configured to perform signal analysis on the response signal. The signal analysis comprises for example spectral analysis, such as a Fourier transformation or the like. The comparison unit determines a comparison result and outputs this to the determination unit. The comparison result may for example comprise a deviation of the acquired response signal from the predetermined response signal.

The determination unit is configured for example to compare a deviation of the acquired response signal from the predetermined response signal as identified by the comparison unit with a threshold value. When the deviation is greater than or equal to the threshold value, a defect is present, for example.

The test device can be designed as a hand-held device that is mobile and ready for use with little effort. By way of example, the test device is designed as a stand-alone test device that comprises an integrated battery for supplying power to the test device.

The test device can have an output unit by way of which a respective determination result is output to a user and/or to a control computer. The output unit may comprise a display device that is integrated in the test device, such as a flat screen, or a communication interface. The communication interface may be designed in wired or else wireless form.

The test device furthermore can have a control unit that is configured to control the test device. By way of example, the control unit controls the multiplexing unit and prompts the generation unit to generate the respective test signal. As an alternative, the test device may also be able to be controlled by an external control unit, wherein the external control unit is for example connected to the test device in terms of communication via a communication interface.

According to one embodiment of the test device, a number of the electrical contacts provided by the plug connector is greater than or equal to the multiplicity of electrical lines of the interface.

This can help ensure that all of the electrical lines of the interface are able to be coupled simultaneously to the test device, such that all possible pairings of electrical lines are able to be checked.

According to an embodiment of the test device, this comprises a test mode unit that is configured to selectively operate a first electronics region of the electronics unit in order to check an intended function of the first electronics region, wherein the first electronics region is part of the electronics unit and has a number of electrical and/or electronic component parts, and wherein the first electronics region, during operation, generates a thermal power loss that is less than or equal to a predetermined threshold value.

The first electronics region of the electronics unit has the features that have already been explained above for the first electronics region in connection with the first aspect.

The test mode unit is configured to apply a test signal and/or an operating voltage to more than two electrical lines of the interface in order to operate the first electronics region.

According to a fifth aspect, what is proposed is an arrangement having an optical system according to the third aspect and having a test device according to the fourth aspect.

The test device is connected, via the interface, to the optical system in order to check the interface according to the method of the first aspect.

The optical system in this arrangement can be currently being constructed, that is to say is not yet ready for operation. By way of example, the optical system is in a number of individual parts that are assembled or integrated step-by-step to form the finished optical system.

“A” or “an” in the present case should not necessarily be understood to be restrictive to exactly one element. Rather, a plurality of elements, such as, for example, two, three or more, may also be provided. Any other numeral used here, too, should not be understood to the effect that there is a restriction to exactly the stated number of elements. Rather, numerical deviations upwards and downwards are possible, unless indicated to the contrary.

Further possible implementations of the disclosure also comprise not explicitly mentioned combinations of any features or embodiments that are described above or below with respect to the exemplary embodiments. In this case, a person skilled in the art will also add individual aspects as improvements or supplementations to the respective basic form of the disclosure.

Further refinements and aspects of the disclosure are the subject matter of the dependent claims and also of the exemplary embodiments of the disclosure that are described below. The disclosure is explained in greater detail below on the basis of embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic exemplary embodiment of a ready-for-operation optical system with an optics module and an interface;

FIG. 3A shows a schematic exemplary embodiment of checking an interface of an electronics unit in a first state of integration;

FIG. 3B shows a schematic exemplary embodiment of checking an interface of an electronics unit in a second state of integration;

FIG. 3C shows a schematic exemplary embodiment of checking an interface of an electronics unit in a third state of integration;

FIG. 4 shows a schematic exemplary embodiment of a wiring configuration of an input of an electronics unit;

FIG. 5 shows a schematic exemplary embodiment of a test device;

FIG. 6A shows a schematic first exemplary embodiment of an internal structure of an electronics unit;

FIG. 6B shows a schematic second exemplary embodiment of an internal structure of an electronics unit;

FIG. 7 shows a schematic block diagram of an exemplary embodiment of a method for checking an interface; and

FIG. 8 shows a schematic block diagram of an exemplary embodiment of a method for producing an optical system.

### DETAILED DESCRIPTION

Unless indicated otherwise, elements that are identical or functionally identical have been given the same reference signs in the figures. It should also be noted that the illustrations in the figures are not necessarily true to scale.

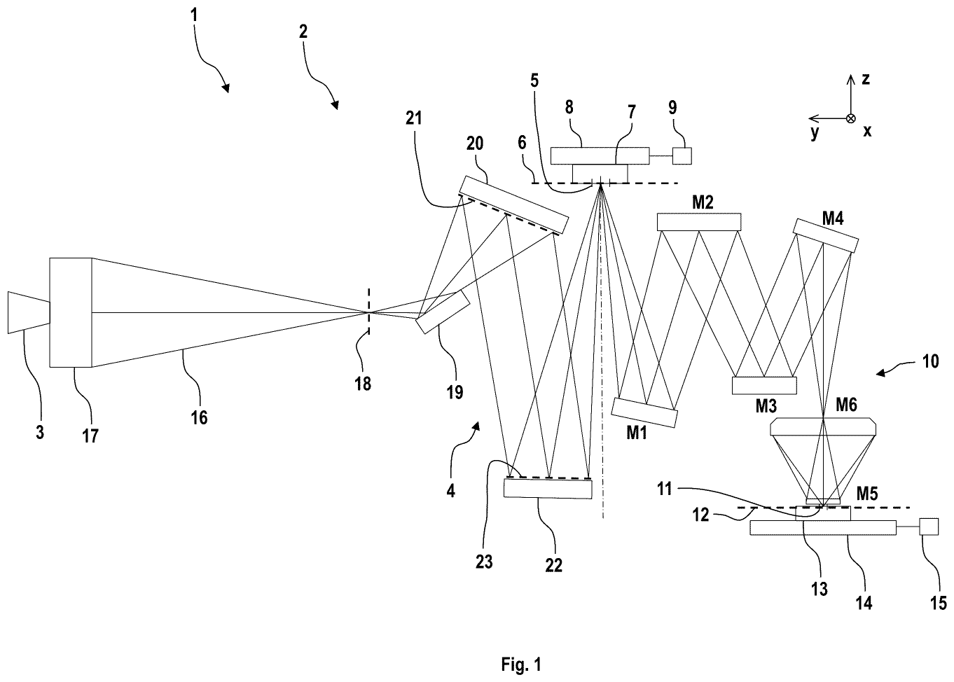

FIG. 1 shows an embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs along the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6.

Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction y. The displacement, on the one hand, of the reticle 7 by way of the reticle displacement drive 9 and, on the other hand, of the wafer 13 by way of the wafer displacement drive 15 may take place in such a way as to be synchronized with one another.

The light source 3 is an EUV radiation source. The light source 3 emits, in particular, EUV radiation 16, which is also referred to below as used radiation, illumination radiation or illumination light. For example, the used radiation 16 has a wavelength in the range between 5 nm and 30 nm. The light source 3 may be a plasma source, for example an LPP (laser produced plasma) source or a DPP (gas-discharge produced plasma) source. It may also be a synchrotron-based radiation source. The light source 3 may be an FEL (free-electron laser).

The illumination radiation 16 emerging from the light source 3 is focused by a collector 17. The collector 17 may be a collector with one or more ellipsoidal and/or hyperboloidal reflection surfaces. The at least one reflection surface of the collector 17 may be impinged upon by the illumination radiation 16 with grazing incidence (GI), that is to say with angles of incidence greater than 45°, or with normal incidence (NI), that is to say with angles of incidence less than 45°. The collector 17 may be structured and/or coated, firstly, for optimizing its reflectivity for the used radiation and, secondly, for suppressing extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect that goes beyond the purely deflecting effect. Alternatively or in addition, the deflection mirror 19 may be in the form of a spectral filter that separates a used light wavelength of the illumination radiation 16 from extraneous light with a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, such as as rectangular facets or as facets with an arcuate edge contour or an edge contour of part of a circle. The first facets 21 may be embodied as plane facets or, alternatively, as facets with convex or concave curvature.

As known for example from DE 10 2008 009 600 A1, the first facets 21 themselves may also be composed in each case of a multiplicity of individual mirrors, such as a multiplicity of micromirrors. The first facet mirror 20 may be designed as a microelectromechanical system (MEMS system). For details, reference is made to DE 10 2008 009 600 A1.

Between the collector 17 and the deflection mirror 19, the illumination radiation 16 travels horizontally, that is to say along the y-direction y.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 consequently forms a doubly faceted system. This basic principle is also referred to as a fly's eye integrator.

It may be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

In a further embodiment, not illustrated, of the illumination optical unit 4, a transfer optical unit contributing to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit may comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 by way of the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are similarly possible. The projection optical unit 10 is a twice-obscured optical unit. The penultimate mirror M5 and the last mirror M6 each have a through opening for the illumination radiation 16. The projection optical unit 10 has an image-side numerical aperture that is greater than 0.5 and may also be greater than 0.6, and may be for example 0.7 or 0.75.

Reflection surfaces of the mirrors Mi may be embodied as free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, for example with alternating layers of molybdenum and silicon.

The projection optical unit 10 has a large object-image offset in the y-direction y between a y-coordinate of a centre of the object field 5 and a y-coordinate of the centre of the image field 11. In the y-direction y, this object-image offset may be of approximately the same magnitude as a z-distance between the object plane 6 and the image plane 12.

For example, the projection optical unit 10 may have an anamorphic form. For example, it has different imaging scales βx, βy in the x-and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, that is to say in a direction perpendicular to the scanning direction.

The projection optical unit 10 leads to a reduction in size of 8:1 in the y-direction y, that is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-and y-directions x, y are known from US 2018/0074303 A1.

In each case one of the second facets 23 is assigned to exactly one of the first facets 21 for respectively forming an illumination channel for illuminating the object field 5. This may produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 can be as homogeneous as possible. It can have a uniformity error of less than 2%. The field uniformity may be achieved by way of the overlay of different illumination channels.

The full-area illumination of the entrance pupil of the projection optical unit 10 may be defined geometrically by an arrangement of the second facets 23. The intensity distribution in the entrance pupil of the projection optical unit 10 may be set by selecting the illumination channels, such as the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner may be achieved by a redistribution of the illumination channels.

Further aspects and details of the illumination of the object field 5 and of the entrance pupil of the projection optical unit 10 are described below.

For example, the projection optical unit 10 may have a homocentric entrance pupil. The latter may be accessible. It may also be inaccessible.

The entrance pupil of the projection optical unit 10 frequently cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the distance of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 22 and the reticle 7. With the aid of this optical element, the different poses of the tangential entrance pupil and the sagittal entrance pupil may be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted in relation to an arrangement plane defined by the deflection mirror 19. The first facet mirror 20 is arranged so as to be tilted with respect to an arrangement plane defined by the second facet mirror 22.

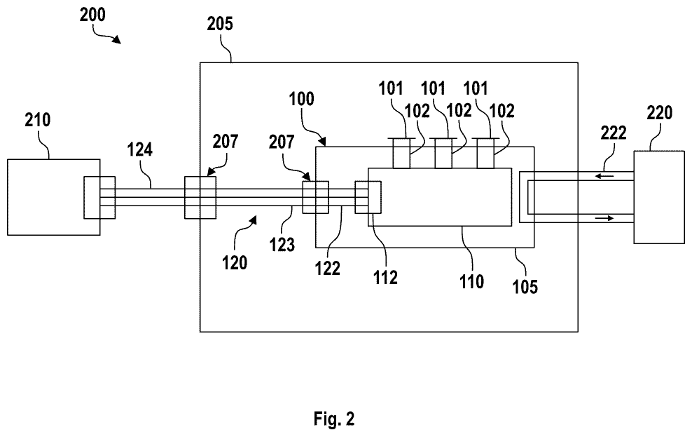

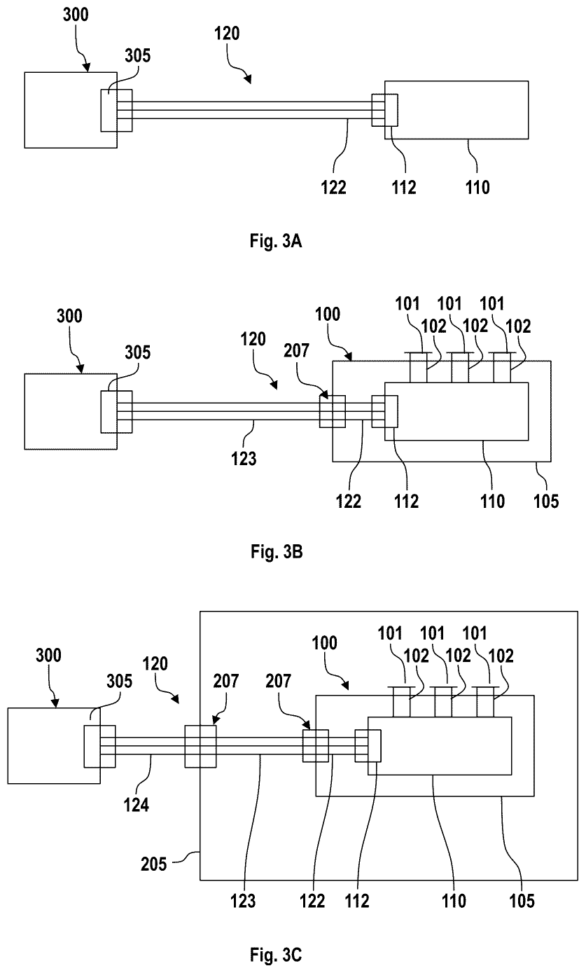

The projection exposure apparatus 1, the illumination system 2, the illumination optical unit 4 and the projection optical unit 4 are examples of a respective optical system 200 (see FIG. 2). The first facet mirror 20, the second facet mirror 22 or else each of the mirrors M1-M6 are examples of a respective optics module 100 (see FIG. 2, 3B or 3C). The individual facets 21, 23 of the facet mirrors 20, 22 are examples of optical elements 101 (see FIGS. 2, 3B, 3C) of the optics module 100.

In order to individually actuate the facets 21, 22 or other displaceable optical elements 101 of the respective optics module 100, a respective optics module 100 has an electronics unit 110 (see FIG. 2, 3A, 3B, 3C, 4, 6A or 6B) and actuator/sensor devices 102 (see FIGS. 2, 3B, 3C) assigned to the optical elements 101. Control data or control signals that are provided by a control computer 201 (see FIG. 2) or the like to the respective optics module 100 in order to control or regulate the position of the individual optical elements 101 are transmitted for example via a wired interface 120 (see FIG. 2, 3A-3C, 6A or 6B).

FIG. 2 shows a schematic exemplary embodiment of a ready-for-operation optical system 200 with an optics module 100 and an interface 120. The optical system 200 is for example a projection exposure apparatus or part of one of these, such as an illumination optical unit 4 or a projection optical unit 10. An element of the optical system 200 is the optics module 100, which is arranged in a vacuum housing 205 of the optical system 200. The optics module 100 has a number of displaceable optical elements 101 for guiding radiation, such as EUV light, in the optical system 200, wherein at least one actuator/sensor device 102 for displacing the optical element 101 and/or for acquiring a position of the optical element 101 is assigned to the respective optical element 101. Without restricting generality, in this example, only three optical elements 101 and only three actuator/sensor devices 102 are illustrated. The optics module 100 forms for example one of the facet mirrors 20, 22 from FIG. 1. It is pointed out that the optical system 200 may have more than just one optics module 100. Further optics modules 100 may have an identical or else a different structure than the optics module 100 illustrated here.

The optics module 100 comprises an electronics unit 110 that is configured to actuate the respective actuator/sensor device 102 on the basis of electrical signals received via a wired interface 120. The electronics unit 110 is arranged in a vacuum-tight housing 105, wherein the electronics unit 110 is located in a gas atmosphere under for example normal pressure, that is to say around 1000 hPa. This helps make it possible to use conventional electrical and/or electronic components for the electronics unit 110 instead of ones that are designed specifically for operation in a vacuum. It is thus possible to use comparatively simple and inexpensive production methods to produce the electronics unit 110. The interface 120 connects the electronics unit 110 in this example to a control computer 210 arranged outside the vacuum housing 205. The control computer 210 is for example configured to control and/or regulate the optics module 100. Due to the arrangement of the optics module 100 in the vacuum housing 205 of the optical system 200, which is for example evacuated during operation of the optical system 200 to a residual gas pressure of 10⁻⁴-10⁻⁷ Pascal (Pa), the optics module 100, and for example the electronics unit 110 and the actuator/sensor devices 102, are not able to be cooled via a conventional air cooling system. Instead, provision is made for example for a fluid cooling system 220, such as a water cooling system. The fluid cooling system 220 comprises a cooling circuit 222 that leads from the fluid cooling system 220 arranged outside the vacuum housing 205 through the vacuum housing 205 to the optics module 100. In this example, the cooling circuit 222 also runs through the vacuum-tight housing 105, but this is not mandatory. In some embodiments, the cooling circuit 222 reaches only up to the vacuum-tight housing 105 and is thermally coupled to a heat sink of the vacuum-tight housing 105 (not illustrated). When producing the optical system 200, providing the ready-for-operation fluid cooling system 220 can be highly cumbersome.

In this example, the interface 120 comprises multiple sections 122, 123, 124, 207. Each section 122, 123, 124, 207 comprises a respective bundle containing a multiplicity of electrical lines, three lines being illustrated by way of example. The bundles 122, 123, 124 are designed for example as cable bundles. The bundles 207 are designed for example as vacuum interfaces that are arranged in the vacuum housing 205 and in the vacuum-tight housing 105. Each bundle 122, 123, 124, 207 has two ends, wherein the respective end is designed for example as a plug or as a socket having a number of contact pins corresponding to the multiplicity of electrical lines. By way of example, the cable bundles 122, 123, 124 each have a plug on their end and the vacuum interfaces 207 each have a socket facing into the respective housing 105, 205 and a socket facing out of the respective housing 105, 205. The sockets and plugs are designed to correspond mechanically to one another, such that a respective plug is able to be plugged into the respective socket. The respective socket with the matching plug together form a plug connector.

It is pointed out that a respective bundle 122, 123, 124, 207 may have multiple sockets/plugs on a respective end, for example because a distributed arrangement of the sockets/plugs on the respective housing 105, 205 and/or the electronics unit 110 is used due to a cramped installation space. By way of example, one of the cable bundles 122, 123, 124 may be designed in the manner of a breakout cable, wherein multiple cables emanate from a first plug at a first end of the bundle and open out into multiple plugs and/or sockets at a second end of the bundle. Likewise, the respective vacuum interface 207 may comprise multiple plugs and/or sockets on a first side of the respective housing 105, 205 and have just a single plug or a single socket on the other side of the housing 105, 205. A respective bundle may additionally have multiple plugs and/or sockets at both ends.

The first bundle 122 is coupled on one side to an input 112 of the electronics unit 110 and coupled at the other end to the vacuum interface 207 of the vacuum-tight housing 105. The second bundle 123 is coupled on one side to the vacuum interface 207 of the vacuum-tight housing 105 and coupled at the other end to the vacuum interface 207 of the vacuum housing 205. The third bundle 124 is coupled on one side to the vacuum interface 207 of the vacuum housing 205 and coupled at the other end to the control computer 210.

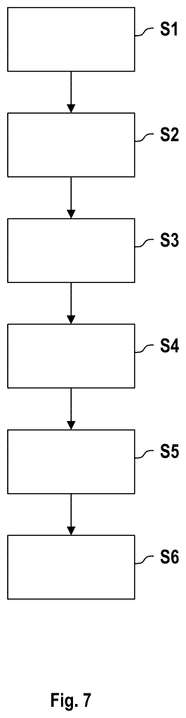

When producing or integrating the optical system 200, this is constructed for example in steps, with for example the electronics unit 110 first being installed in the vacuum-tight housing 105. In this case, the first bundle 122 for example also has to be connected first to the input 112 and then to the vacuum interface 207. Errors or defects may occur in these coupling processes; for example, a contact pin in one of the plug connectors involved is bent or breaks in the process, which for example remains unnoticed by a worker performing these tasks. The same applies to the further integration steps, such as for example installation of the optics module 100 in the vacuum housing 205. The interface 120 is therefore checked following each coupling process or integration step. For this purpose, for example, the test device 300 explained with reference to FIG. 5 is used and the method described with reference to FIG. 7 is applied. This is illustrated by way of example for multiple integration steps during the production of an optical system 200 with reference to FIGS. 3A-3C.

FIG. 3A in this case shows a first integration step in which for example a first bundle 122 is coupled to the input 112 of the electronics unit 110. In this state, the interface 120 therefore comprises only the first bundle 122 coupled to the input 112. The test device 300 is connected to the free end of the first bundle 122 (see FIG. 5). For this purpose, the test device 300 has a suitable plug connector 305. The test device 300 is then used to check the interface 120. This is explained in detail with reference to FIG. 7. The structure of the test device 300 is explained in detail with reference to FIG. 5. If no defect is identified in the check, the integration may be continued.

FIG. 3B shows a second integration step in which for example the electronics unit 110 is installed in the vacuum-tight housing 105. The actuator/sensor devices 102 and the optical elements 101 are furthermore coupled here to the electronics unit 110, so as to provide the optics module 100. In this second integration step, the first bundle 122 has been coupled to a first side of the vacuum interface 207 in the vacuum-tight housing 105, and a second bundle 123 has been coupled on the second side of the vacuum interface 207. In this state, the interface 120 thus comprises the first and the second bundle 122, 123 and the vacuum interface 207. The test device 300 is connected to the free end of the second bundle 123 and the interface 120 is checked again. If no defect is identified in the check, the integration may be continued.

FIG. 3C shows a third integration step in which for example the optics module 100 is installed in the vacuum housing 205 of the optical system 200 (see FIG. 2). In this third integration step, the second bundle 123 has been coupled to a first side of the vacuum interface 207 in the vacuum housing 205, and a third bundle 124 has been coupled on the second side of the vacuum interface 207. In this state, the interface 120 thus comprises the first, second and bundle 122, 123, 124 and the vacuum interface 207. The test device 300 is connected to the free end of the third bundle 124 and the interface 120 is checked again. If no defect is identified in the check, the integration may be continued.

Further integration steps comprise installing and providing the fluid cooling system 220 (see FIG. 2) used for the operation of the optics module 100 during operation of the optical system 200.

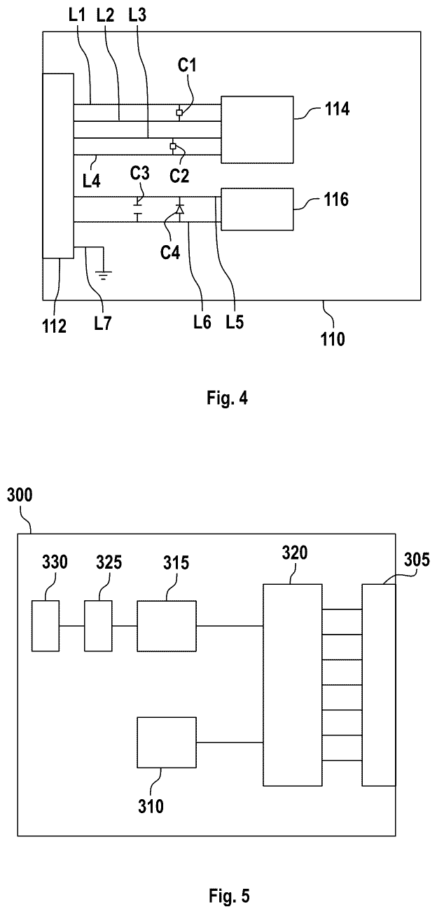

FIG. 4 shows a schematic exemplary embodiment of a wiring configuration of an input 112 of an electronics unit 110. The electronics unit 110 of the optics module 100 from FIG. 2 is involved here, for example. In this example, the electronics unit 110 has two processing units 114, 116. Integrated circuits, such as processors, ASICs and the like, or else power electronics that provide an electric power for actuating the actuator/sensor devices 102 (see FIGS. 2, 3B, 3C) are involved here, for example. In this example, the actuation unit 114 is connected to the input 112 by way of four electrical conductors L1-L4 and the actuation unit 116 is connected to the input 112 by way of two electrical conductors L5, L6. A seventh line provides a ground potential. By way of example, the electronics unit 110 is integrated on a circuit board, wherein the electrical lines L1-L7 are in the form of conductor tracks on the circuit board. The input 112 is designed for example as a plug or socket with respective contact pins for the electrical lines L1-L7.

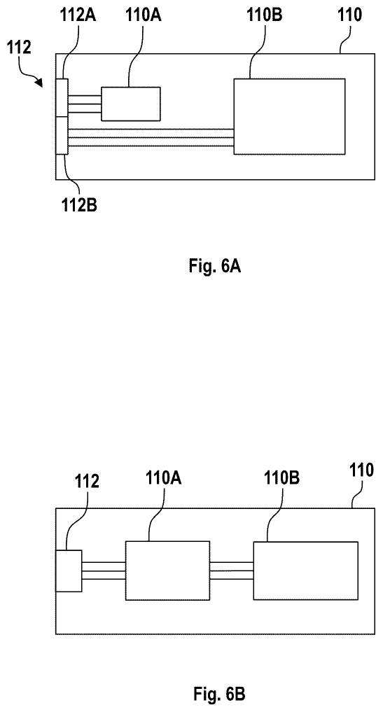

The input 112 may also comprise multiple plugs and/or sockets that are physically separate from one another, as illustrated for example with reference to FIG. 6A. It is pointed out that this structure is merely exemplary and the electronics unit 110 is not restricted thereto. On the contrary, in other embodiments, the electronics unit 110 may have additional and/or other actuation units and may also comprise more or fewer than the illustrated seven electrical lines L1-L7.

A respective pair of lines of the input 112 in this example has a specific wiring configuration with electrical and/or electronic components C1-C4, such that a respective pair of electrical lines L1-L7 has a predetermined passive input behaviour. The specific passive input behaviour is able to be determined using an electrical test signal. Since the passive input behaviour is determined following a respective coupling of a further bundle 122, 123, 124, 207 (see FIG. 2 or 3A-3C) to the interface 120, it is thus possible to check whether the respective electrical contact between the bundles 122, 123, 124, 207 has been established as intended, such that the interface 120 is configured to transmit the respective electrical signals during operation of the optics module 100 (see FIG. 2, 3B or 3C) or of the optical system 200 (see FIG. 2).

By way of example, the components C1 and C2 are each in the form of an electrical resistance having a specific value. The electrical resistance is able to be determined by applying a DC voltage (test signal) between the pair of lines L1 and L2 or L3 and LA and measuring the current flow (response signal) that arises. A voltage may also be applied between the lines L1 and L3 or L4, for example. Since these lines are not connected in the electronics unit 110, as long as the electronics unit 110 is not operated (that is to say the processing unit 114 is deactivated), no current flow will arise, that is to say an infinite electrical resistance will be determined. The component C3 is for example in the form of a capacitor with a specific capacitance and the component C4 is for example in the form of a semiconductor diode. In this wiring configuration, a current flow should arise between the lines L5 and L6 only when this has the correct polarity in relation to a forward direction of the diode C4. An AC voltage signal (test signal) may also for example be used to determine the capacitance of the capacitor C3 by measuring a phase (response signal) between current and voltage.

The respective test signal can be applied to all possible pairwise combinations of the lines L1-L7. It is thus possible to determine all possible faulty contacts along the interface 120.

By way of example, the passive input behaviour is determined beforehand for all pairwise combinations of the lines L1-L7 using the test signal, that is to say before the first bundle 122 is coupled to the input 112. A respective response signal is acquired here for a respective line pair. All of the response signals together form the passive input behaviour of the input 112, for example. The response signals determined in this way are then used as the respective predetermined response signal when checking the interface 120 (see method step S5 of the method from FIG. 7).

It is pointed out that all or some of the components C1-C4 illustrated in FIG. 4 may be part of the respective actuation unit 114, 116.

FIG. 5 shows a schematic exemplary embodiment of a test device 300 that may be used for example in the method from FIG. 7 to check an interface 120 (see FIG. 2 or 3A-3C). The test device 300 is configured to check the interface 120 for the wired transmission of electrical signals to an electronics unit 110 (see FIGS. 2, 3A-3C, 4, 6A, 6B), arranged in a vacuum-tight housing 105 (see FIGS. 2, 3A-3C), of an optics module 100 (see FIGS. 2, 3B, 3C). The interface 120 comprises at least one first bundle 122 (see FIGS. 2, 3A-3C) containing a multiplicity of electrical lines, which first bundle 122 is coupled to corresponding contacts of the electronics unit 110.

The test device 300 comprises a plug connector 305 for connecting the test device 300 to a free end of the first bundle 122 of electrical lines, The plug connector 305 may be designed as a socket and/or as a plug. The plug connector 305 is furthermore configured for connection to a respective further bundle 123, 124, 207 (see FIGS. 2, 3B, 3C) of the interface 120. The test device 300 furthermore comprises a generation unit 310, which is configured to generate an electrical test signal for checking a pair of electrical lines, and an acquisition unit 315, which is configured to acquire a response signal when the test signal is applied to the pair of electrical lines. The generation unit 310 comprises a current source, a voltage source and/or a function generator. The acquisition unit 315 comprises measuring units for acquiring a current, a voltage and/or a phase between current and voltage. The test device 300 additionally comprises a multiplexing unit 320 for connecting a respective pair of electrical lines of the bundle 122, 123, 124, 207 coupled to the plug connector 305 to the generation unit 310 and to the acquisition unit 315. The test device 300 additionally has a comparison unit 325 for comparing the acquired response signal for the pair of electrical lines with a response signal predetermined for the pair, and a determination unit 330. The determination unit 330 is configured to determine, on the basis of the comparison, whether a defect is present in one of the electrical lines of the pair.

FIG. 6A shows a schematic first exemplary embodiment of an internal structure of an electronics unit 110. In this example, the electronics unit 110 has two electronics regions 110A, 110B separate from one another. The respective electronics region 110A, 110B has a number of electrical and/or electronic component parts; for example, these are resistors, capacitors, coils, diodes, transistors, logic gates and/or highly integrated circuits such as processors, ASICs, storage elements and the like. The first electronics region 110A is designed such that it generates, during operation, a thermal power loss that is less than or equal to a predetermined threshold value. The second electronics region 110B is designed such that it generates, during operation, a thermal power loss above the predetermined threshold value. The threshold value for the thermal power loss is in this case defined such that the electronics unit 110 continuously withstands the thermal power loss up to the threshold value without active cooling of the electronics unit 110, that is to say does not overheat. By way of example, the thermal power loss is transferred to the vacuum-tight housing 105 (see FIG. 2) through heat transfer and emitted therefrom as thermal radiation. The first electronics region 110A may thus be operated continuously without active cooling. The first electronics region 110A is additionally able to be operated independently of the second electronics region 110B.

In this example, the input of the electronics unit 110 is divided into two. A first part 112A in this case provides the contacts that connect the first electronics region 110A to the input, and a second part 112B provides the contacts that connect the second electronics region 110B to the input 112. The first and the second part 112A, 112B may be designed as plugs and/or sockets that are arranged separately from one another on the electronics unit 110.

When the electronics unit 110 is designed as illustrated here, then the test device 300 (see FIG. 5) is configured to check the interface 120 (see FIGS. 2, 3A-3C) when the electronics unit 110 is installed in an optics module 100 (see FIGS. 2, 3B, 3C) for an optical system 200 (see FIG. 2), optionally additionally configured to operate the first electronics region 110A and to check the intended function thereof. For this purpose, the test device 300 comprises for example a test mode unit (not illustrated).

FIG. 6B shows a schematic second exemplary embodiment of an internal structure of an electronics unit 110. This is a deviation from the electronics unit 110 from FIG. 6A, with no separate inputs 112A, 112B as in that figure being provided, but rather only a single input 112. The first electronics region 110A and the second electronics region 110B also share multiple lines within the electronics unit 110. It could also be said that some of the lines through the first electronics region 110A are daisy-chained. It is pointed out that, apart from the illustrated lines, further, separate lines for the first and/or second electronics region 110A, 110B may also be present. In this second exemplary embodiment too, the first electronics region 110A is able to be operated independently of the second electronics region 110B.

FIG. 7 shows a schematic block diagram of one exemplary embodiment of a method for checking an interface 120 (see FIGS. 2, 3A-3C) for the wired transmission of electrical signals to an electronics unit 110 (see FIGS. 2, 3A-3C, 4, 6A, 6B), arranged in a vacuum-tight housing 105 (see FIG. 2), of an optics module 100 (see FIGS. 2, 3B, 3C). By way of example, the optics module 100 of the optical system 200 from FIG. 2 is involved. The electronics unit 110 is designed for example as explained with reference to FIG. 4 or 6, 6B. The optics module 100 has a number of displaceable optical elements 101 (see FIGS. 2, 3B, 3C) for guiding radiation, wherein at least one actuator/sensor device 102 (see FIGS. 2, 3B, 3C) for displacing the optical element 101 and/or for acquiring a position of the optical element 101 is assigned to the respective optical element 101. The electronics unit 110 is configured to actuate the respective actuator/sensor device 102 on the basis of electrical signals received via the interface 102. The interface 120 comprises at least one first bundle 122 containing a multiplicity of electrical lines, which first bundle 122 is able to be coupled to corresponding contacts of the electronics unit 110.

In a first step S1, the first bundle 122 is coupled to the electronics unit 110. In a second step S2, a test device 300, for example the test device from FIG. 5, is connected to a free end of the first bundle 122. This state is illustrated for example in FIG. 3A. In a third step S3, an electrical test signal generated by the test device 300 is applied to a specific pair of electrical lines of the first bundle 122. The test signal is for example a DC voltage signal or an AC voltage signal. In a fourth step S4, an electrical response signal from the specific pair of electrical lines is acquired. The fourth step S4 takes place for example at the same time as the third step S3. In a fifth step S5, the acquired response signal is compared with a response signal predetermined for the specific pair. The predetermined response signal may be determined for example in a preceding calibration measurement for the respective electronics unit 110, as explained with reference to FIG. 4. In a sixth step S6, it is determined, on the basis of the comparison, whether a defect is present in one of the electrical lines of the pair.

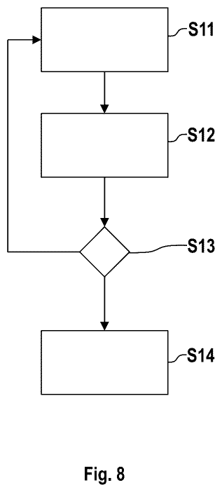

FIG. 8 shows a schematic block diagram of an exemplary embodiment of a method for producing an optical system 200 (see FIG. 2). The optical system 200 comprises an optics module 100 (see FIGS. 2, 3B, 3C) arranged in a vacuum housing 205 (see FIG. 2). The optics module 100 has a number of displaceable optical elements 101 (see FIGS. 2, 3B, 3C) for guiding radiation in the optical system 200, wherein at least one actuator/sensor device 102 (see FIG. 2) for displacing the optical element 101 and/or for acquiring a position of the optical element 101 is assigned to the respective optical element 101. The optics module 100 has an electronics unit 110 (see FIGS. 2, 3A-3C), arranged in a vacuum-tight housing 105, for actuating the respective actuator/sensor device 102 on the basis of electrical signals received via an interface 120 (see FIGS. 2, 3A-3C).

In a first step S11 of the method, the electronics unit 110 is connected for example to a first bundle 122. The interface 120 thus comprises exactly one first section 122. In a second step S12, the free end of the first bundle 122 is connected to a test device 300 (see FIGS. 3A-3C, 5) and the interface 120 is checked, for example as described with reference to the method from FIG. 7. If no defect is identified in this check, the production of the optical system 200 using the electronics unit 110 coupled to the first bundle 122 may be continued. In the following step S13, it is checked whether there are following further production steps concerning the interface 120. If this is the case, steps S11 and S12 are performed again as part of the further production step. By way of example, as a further integration step, the electronics unit 110 is installed in a vacuum-tight housing 105 (see FIGS. 2, 3B, 3C). In this case, the first bundle 122 is coupled for example to a vacuum interface 207 (see FIGS. 2, 3B, 3C) in the vacuum-tight housing 105. The interface 120 is thus expanded by the section 207. Steps S11, S12 are then performed again in relation to the expanded interface 120. The optical system 200 is thereby produced step-by-step, wherein, following each integration step in which the interface 120 is supplemented with a respective bundle 122, 123, 124, 207, the interface 120 is checked again with the test device 300. If it is identified in step S13 that there is no following further production step concerning the interface 120, the method is continued with the integration of the remaining components of the optical system 200, and the optical system 200 is thus produced (step S14). This method thus ensures that the interface 120 has problem-free operation following the production of the optical system 200.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optics module
101 Optical element
102 Actuator/sensor device
105 Vacuum-tight housing
110 Electronics unit
110A Electronics region
110B Electronics region
112 Input
112A Input
112B Input
114 Processing unit
116 Processing unit
120 Interface
122 Bundle
123 Bundle
124 Bundle
200 Optical system
205 Vacuum housing
207 Vacuum interface
210 Control computer
220 Fluid cooling system
222 Cooling circuit
300 Test device
305 Plug-in connector
310 Generation unit
315 Acquisition unit
320 Multiplexing unit
325 Comparison unit
330 Determination unit
C1 Component
C2 Component
C3 Component
C4 Component
L1 Line
L2 Line
L3 Line
LA Line
L5 Line
L6 Line
L7 Line
M1 Mirror
M2 Mirror
M3 Mirror
M4 Mirror
M5 Mirror
M6 Mirror
S1 Method step
S2 Method step
S3 Method step
S4 Method step
S5 Method step
S6 Method step
S11 Method step
S12 Method step
S13 Method step
S14 Method step

What is claimed is:

1. A method of checking an interface for wired transmission of electrical signals to an electronics unit in a vacuum-tight housing of an optics module, the optics module comprising a plurality of displaceable optical elements to guide radiation, an actuator/sensor device being configured to displace one of the optical elements and/or to acquire position information for the one of the optical elements, the electronics unit configured to actuate the actuator/sensor device based on electrical signals received via the interface, the interface comprising a first bundle comprising a plurality of electrical lines, the method comprising:
a) coupling the first bundle to the electronics unit;
b) connecting a test device to the first bundle;
c) applying an electrical test signal generated by the test device to a pair of electrical lines of the first bundle;
d) acquiring an electrical response signal from the pair of electrical lines;
e) comparing the acquired response signal with a predetermined response signal for the pair of electrical lines; and
f) determining whether a defect is present in one of the electrical lines of the pair based on the comparison,
wherein:
the interface comprises a second bundle of electrical lines coupled with the first bundle of electrical lines to provide an extended bundle; and
b)-f) are performed for the extended bundle.

2. The method of claim 1, comprising performing c)-f) for each pair of electrical lines of the first bundle.

3. The method of claim 1, wherein the electrical test signal comprises:
a DC voltage signal for determining an electrical resistance;
an AC voltage signal with a frequency for determining a specific impedance; and/or
an AC voltage signal with a changeable frequency for determining an impedance characteristic.

4. The method of claim 1, further comprising, prior to a), determining the predetermined response signal for each pair of contacts of the electronics unit by applying the test signal to the respective pair of contacts of the electronics unit and acquiring the response signal.

5. The method of claim 1, wherein:
an optics system comprises a vacuum housing and the optics module;
the optics module and the vacuum-tight housing are in the vacuum housing;
the interface comprises a bundle of electrical lines extending through the vacuum housing and a vacuum interface; and
the vacuum interface is on: i) the vacuum-tight housing; and/or ii) the vacuum housing.

6. The method of claim 5, further comprising using a fluid cooling system to actively cooling the electronics unit during operation of the optics module.

7. The method of claim 1, further comprising using a fluid cooling system to actively cooling the electronics unit during operation of the optics module.

8. The method of claim 1, wherein:
the electronics unit comprises a first electronics region containing a plurality of electrical and/or electronic component parts;
during operation, the first electronic region generates a thermal power loss that is less than or equal to a predetermined threshold value;
the electronics unit comprises a second electronics region containing a plurality of electrical and/or electronic component parts;
during operation, the second electronics region generates a thermal power loss above the predetermined threshold value;
the first electronics region is operable independently of the second electronics region; and
the method further comprises:
operating the first electronics region; and
checking an intended function of the first electronics region.

9. The method of claim 8, comprising performing c)-f) for each pair of electrical lines of the first bundle.

10. The method of claim 8, wherein the electrical test signal comprises:
a DC voltage signal for determining an electrical resistance;
an AC voltage signal with a frequency for determining a specific impedance; and/or
an AC voltage signal with a changeable frequency for determining an impedance characteristic.

11. The method of claim 8, further comprising, prior to a), determining the predetermined response signal for each pair of contacts of the electronics unit by applying the test signal to the respective pair of contacts of the electronics unit and acquiring the response signal.

12. The method of claim 8, wherein:
an optics system comprises a vacuum housing and the optics module;
the optics module and the vacuum-tight housing are in the vacuum housing;
the interface comprises a bundle of electrical lines extending through the vacuum housing and a vacuum interface; and
the vacuum interface is on: i) the vacuum-tight housing; and/or ii) the vacuum housing.

13. The method of claim 1, further comprising, before a), producing an optical system that comprises the optics module, the actuator sensor, the vacuum-tight housing, and the interface.

14. An optical system, comprising:
an optics module, comprising:
a plurality of displaceable optical elements to guide radiation in the optical system;
an actuator/sensor device configured to displace one of the optical elements and/or to acquire position information for the one of the optical elements;
a vacuum-tight housing; and
an electronics unit in the vacuum-tight housing,
wherein:
the electronics unit is configured to actuate the actuator/sensor device based on electrical signals received via a wired interface;
an input of the electronics unit is coupled to the wired interface;
the input of the electronics unit comprises a plurality of electrical lines that has a wiring configuration with electrical and/or electronic components so that a pair of electrical lines has a passive input behavior that is determinable using an electrical test signal transmitted via the wired interface;
the electronics unit comprises a first electronics region containing a number of electrical and/or electronic component parts;
the first electronics region is configured so that, during operation, the first electronics region generates a thermal power loss that is less than or equal to a threshold value;
the electronics unit comprises a second electronics region containing a number of electrical and/or electronic component parts;
the second electronics region is configured so that, during operation, the second electronics region generates a thermal power loss above the threshold value; and
the first electronics region is operable independently of the second electronics region.

15. The optical system of claim 14, wherein the electrical and/or electronic components comprise a resistor, a capacitor, an inductor and/or a diode.

16. The optical system of claim 14, wherein:
the optical system is a lithography apparatus with a vacuum housing;
the optics module is in the vacuum housing;
the lithography apparatus further comprises a fluid cooling system configured to cool the optics module during operation of the lithography apparatus.

17. The optical system of claim 14, wherein:
the optical system comprises a plurality of optics module;
each optics module comprises:
a plurality of displaceable optical elements to guide radiation in the optical system;
an actuator/sensor device configured to displace one of the optical elements and/or to acquire position information for the one of the optical elements;
a vacuum-tight housing; and
an electronics unit in the vacuum-tight housing; and
for each optics module:
the electronics unit is configured to actuate the actuator/sensor device based on electrical signals received via a wired interface;
an input of the electronics unit is coupled to the wired interface;
the input of the electronics unit comprises a plurality of electrical lines that has a wiring configuration with electrical and/or electronic components so that a pair of electrical lines has a passive input behavior that is determinable using an electrical test signal transmitted via the wired interface;
the electronics unit comprises a first electronics region containing a number of electrical and/or electronic component parts;
the first electronics region is configured so that, during operation, the first electronics region generates a thermal power loss that is less than or equal to a threshold value;
the electronics unit comprises a second electronics region containing a number of electrical and/or electronic component parts;
the second electronics region is configured so that, during operation, the second electronics region generates a thermal power loss above the threshold value; and
the first electronics region is operable independently of the second electronics region.

18. The optical system of claim 17, wherein the electrical and/or electronic components comprise a resistor, a capacitor, an inductor and/or a diode.

19. The optical system of claim 17, wherein:
the optical system is a lithography apparatus with a vacuum housing;
each optics module is in the vacuum housing;
the lithography apparatus further comprises a fluid cooling system configured to cool each optics module during operation of the lithography apparatus.

20. A test device configured to check an interface for wired transmission of electrical signals to an electronics unit in a vacuum-tight housing of an optics module, the interface comprising a first bundle comprising a plurality of electrical lines, the first bundle being coupled to the electronics unit, the test device comprising:
a plug connector configured connect the test device to the first bundle of electrical lines;
a generation unit configured to generate an electrical test signal to check the pair of electrical lines;
an acquisition unit configured to acquire a response signal when the test signal is applied to the pair of electrical lines;
a multiplexing unit configured to connect the pair of electrical lines to the generation unit and to the acquisition unit;
a comparison unit configured to compare the acquired response signal for the pair of electrical lines with a predetermined response signal for the pair of electrical lines;
a determination unit configured to determine, based on the comparison, when a defect is present in one of the electrical lines of the pair of electrical lines; and
a test mode unit,
wherein:
the test mode unit is configured to selectively operate a first electronics region of the electronics unit to check an intended function of the first electronics region;
the first electronics region is part of the electronics unit;
the first electronics region comprises a plurality of electrical and/or electronic component parts;
the first electronics region is configured so that, during operation, the first electronics region generates a thermal power loss that is less than or equal to a threshold value;
the test mode unit is configured to selectively operate a second electronics region of the electronics unit to check an intended function of the second electronics region;
the second electronics region is part of the electronics unit; and
the second electronics part comprises a plurality of electrical and/or electronic component parts and that generates, during operation, a thermal power loss above the threshold value.
